(19) United States
(12) Patent Application Publication
(10) Pub. No.: US 2026/0123538 A1
(43) Pub. Date: Apr. 30, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chia-Pu LIANG, Taichung City (TW); Kun-Sheng TSAI, Taichung City (TW); Chung-Yu KE, Taichung City (TW)

(21) Appl. No.: 19/072,207

(22) Filed: Mar. 6, 2025

(30) Foreign Application Priority Data
Oct. 24, 2024 (TW) 113140618

(51) Int. Cl. H01L 25/16; G02B 6/42; H01L 23/13; H01L 23/36; H01L 23/538; H01L 25/00

(52) U.S. Cl. CPC H10W 90/00; G02B 6/4269; H10W 70/611; H10W 70/68; H10W 90/401; H10W 40/10

(57) ABSTRACT

An electronic package and a manufacturing method thereof are provided, in which a carrier board is mounted onto a carrier structure to dispose a first optoelectronic device on the carrier board. At the same time, a groove is formed on the carrier structure to dispose a second optoelectronic device to increase the amount of data transmission per second by increasing the number of optoelectronic devices.

### CROSS-REFERENCE TO RELATED APPLICATIONS

The present application is based upon and claims the right of priority to TW Patent Application No. 113140618, filed Oct. 24, 2024, the disclosure of which is hereby incorporated by reference herein in its entirety for all purposes

### BACKGROUND

### 1. Technical Field

The present disclosure relates to a semiconductor device, and more particularly, to an electronic package with an optoelectronic device and a manufacturing method thereof.

### 2. Description of Related Art

With the vigorous development of the electronics industry, electronic products are gradually moving towards multi-function and high performance. The application of the current fifth-generation (5G) communication technology has expanded to the internet of things (IoT), industrial internet of things (IIoT), cloud, artificial intelligence (AI), autonomous cars, medical and other fields. Moreover, with the expansion of the application, a very large amount of data needs to be efficiently transmitted, calculated and stored. In particular, the demand for data transmission has emerged in large numbers, causing the industry to begin to use “light” instead of “electricity” as the carrier of data transmission so as to improve the transmission capacity, efficiency, or distance and to reduce the energy consumption during the transmission process. Against this background, co-package optics has become the development trend of future semiconductor and packaging technology.

FIG. 1 is a schematic cross-sectional view of a conventional semiconductor package 1 for co-package optics. An electronic element 11, an electronic integrated circuit (EIC) element 12 and a photonic integrated circuit (PIC) element 13 bonded on top of the electronic integrated circuit element 12 are respectively disposed on a substrate 10 of the semiconductor package 1. An optical fiber 14 is connected to one side of the photonic integrated circuit element 13, and a shelf 15 is provided below the connection point between the photonic integrated circuit element 13 and the optical fiber 14.

However, existing semiconductor packages used for optical communications are limited by their packaging technology and structure, and most of them can only connect one optical fiber. As a result, the transmission speed of existing optical fiber communications (i.e., the amount of data transmitted per unit time) has encountered a bottleneck and is gradually insufficient, let alone cope with the rapid and drastic increase in data transmission demand of future technologies and products.

Therefore, how to overcome the above-mentioned drawbacks of the prior art has become an urgent issue to be solved.

### SUMMARY

In view of the various deficiencies of the prior art, the present disclosure provides an electronic package, which comprises: a carrier structure having a first surface and a second surface opposite to the first surface, wherein the first surface is formed with a groove thereon; a carrier board disposed on the first surface of the carrier structure and electrically connected to the carrier structure; a first optoelectronic device disposed on and electrically connected to the carrier board; and a second optoelectronic device disposed in the groove and electrically connected to the carrier structure.

The present disclosure further provides a method of manufacturing an electronic package, the method comprises: disposing a carrier board on a carrier structure, wherein the carrier structure has a first surface and a second surface opposite to the first surface, and a groove is formed on the first surface, wherein the carrier board is disposed on the first surface of the carrier structure and is electrically connected to the carrier structure; disposing a first optoelectronic device on the carrier board and electrically connecting the first optoelectronic device to the carrier board; and disposing a second optoelectronic device in the groove and electrically connecting the second optoelectronic device to the carrier structure.

In the aforementioned electronic package and method, the present disclosure further comprises disposing an electronic element on the carrier board and electrically connecting the electronic element to the carrier board.

In the aforementioned electronic package and method, the present disclosure further comprises disposing a heat sink on the first optoelectronic device and/or the second optoelectronic device.

In the aforementioned electronic package and method, the first optoelectronic device and the second optoelectronic device are each connected to at least one optical fiber.

In the aforementioned electronic package and method, the carrier board is a core substrate with a circuit layer, a coreless substrate with a circuit layer, or an interposer with conductive vias.

In the aforementioned electronic package and method, the first optoelectronic device and the second optoelectronic device each comprises a package structure, a semiconductor element disposed in the package structure and an optical element mounted onto the package structure.

In the aforementioned electronic package and method, the optical element is an optical module, and the optical module includes a coupler, an optical chip, a total reflection mirror and an optical fiber array unit. The optical element may also be an optical chip.

In the aforementioned electronic package and method, the package structure is a fan-out package-on-package structure, and the semiconductor element is an electronic integrated circuit.

As can be seen from the above, in the electronic package and the manufacturing method thereof of the present disclosure, a carrier board is additionally disposed on the carrier structure for connecting the first optoelectronic device. At the same time, a groove is formed in the carrier structure for mounting the second optoelectronic device, so that the amount of data transmission is increased by increasing the number of optoelectronic devices.

### BRIEF DESCRIPTION OF THE DRAWINGS

FIG. 1 is a schematic cross-sectional view of a conventional semiconductor package for co-package optics.

FIG. 2A to FIG. 2C are schematic cross-sectional views illustrating a manufacturing method of an electronic package according to a first embodiment of the present disclosure.

FIG. 3A to FIG. 3C are schematic cross-sectional views illustrating a manufacturing method of an electronic package according to a second embodiment of the present disclosure.

FIG. 4 is a schematic cross-sectional view of an electronic package according to a third embodiment of the present disclosure.

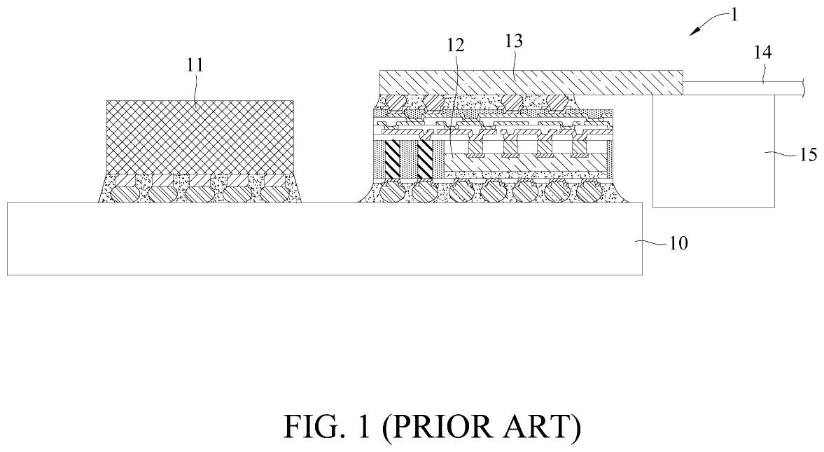

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “third,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

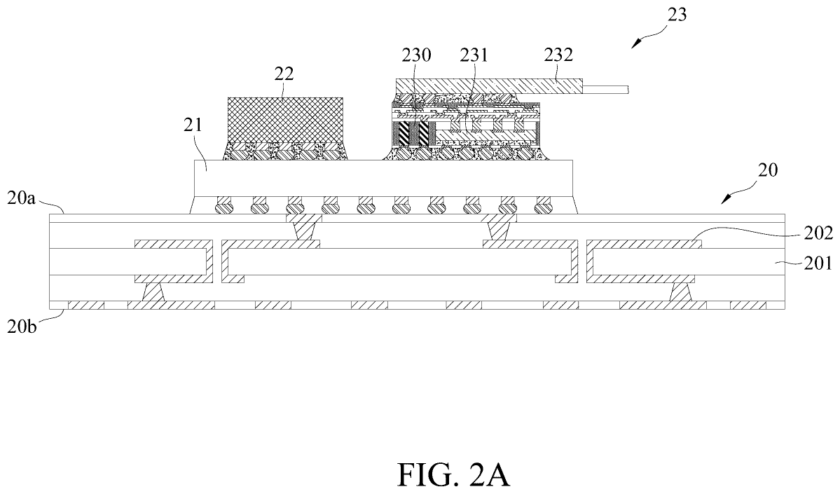

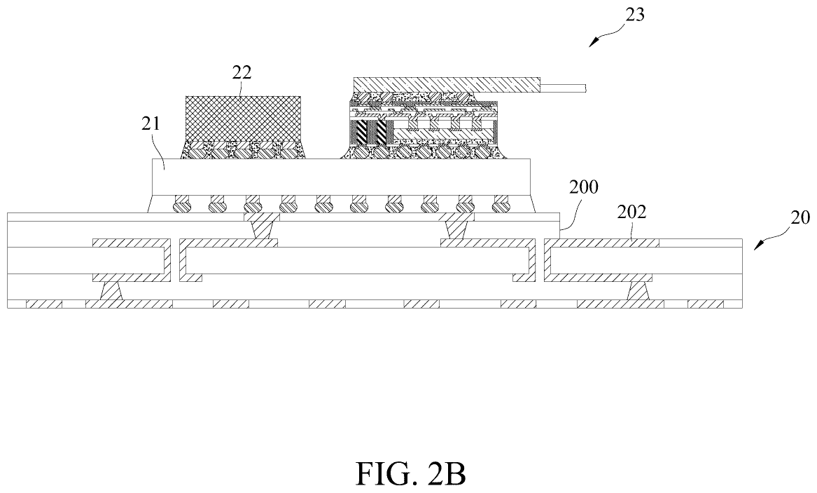

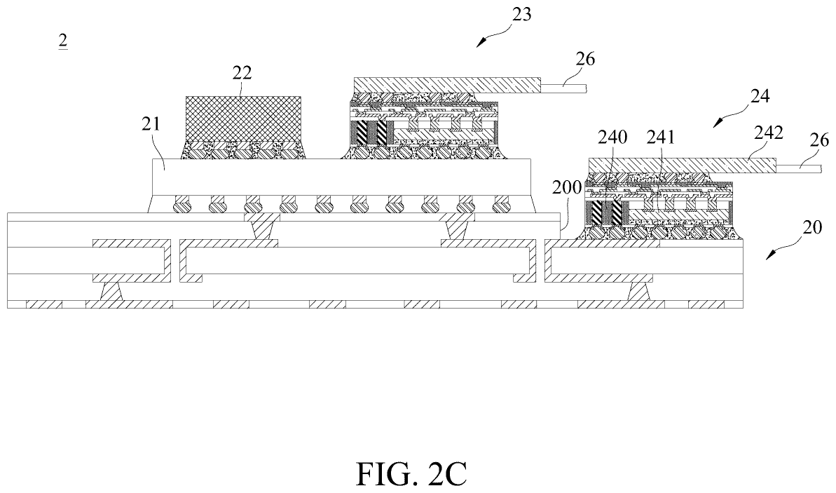

Please refer to FIG. 2A to FIG. 2C, which are schematic cross-sectional views illustrating a manufacturing method of an electronic package 2 according to a first embodiment of the present disclosure.

As shown in FIG. 2A, a carrier structure 20 having a first surface 20a and a second surface 20b opposite to the first surface 20a is first provided. The carrier structure 20 is, for example, a redistribution layer (RDL) structure or a semiconductor package substrate. The carrier structure 20 in this embodiment is a semiconductor package substrate, such as a package substrate with a core layer or a circuit structure without a core layer (coreless), and the circuit structure includes at least one insulating layer 201 and at least one circuit layer 202 bonded to the insulating layer 201. The insulating layer 201 is made of dielectric material such as polybenzoxazole (PBO), polyimide (PI), prepreg (PP), or the like. The circuit layer 202 is, for example, a fan-out type redistribution layer.

Then, a carrier board 21, an electronic element 22 and a first optoelectronic device 23 are disposed on the first surface 20a of the carrier structure 20, wherein the electronic element 22 and the first optoelectronic device 23 are electrically connected to the carrier board 21, and the carrier board 21 is electrically connected to the carrier structure 20.

The carrier board 21 is, for example, a core substrate with a circuit layer, a coreless substrate with a circuit layer, or an interposer with conductive vias, and the carrier board 21 can be mounted and electrically connected to the first surface 20a of the carrier structure 20 via a plurality of conductive elements.

The electronic element 22 is, for example, an active element such as a switch chip, a system-on-chip (SOC), a high bandwidth memory (HBM) chip, or other functional chips, or the electronic element 22 can be a passive element such as a resistor, a capacitor, or an inductor. The electronic element 22 can be electrically connected to the carrier board 21 in a flip-chip manner via a plurality of conductive bumps such as solder bumps, copper bumps, or others.

The first optoelectronic device 23 includes a package structure 230, a semiconductor element 231 disposed in the package structure 230, and an optical element 232 mounted onto the package structure 230. The package structure 230 is, for example, a fan-out package-on-package (FO-POP) structure. The semiconductor element 231 is, for example, an electronic integrated circuit (EIC). The optical element 232 is an optical module (PIC module), which includes, for example, a coupler, an optical chip, a total reflection mirror, a fiber array unit (FAU), and the like. The optical element 232 can also be an optical chip.

In addition, in the aforementioned manufacturing process, the carrier board 21 can be first mounted to the carrier structure 20, and then the electronic element 22 and the first optoelectronic device 23 are disposed on the carrier board 21. Alternatively, the electronic element 22 and the first optoelectronic device 23 can be mounted to the carrier board 21 first, and then the carrier board 21 is disposed on the carrier structure 20.

As shown in FIG. 2B, a groove 200 is formed on the first surface 20a of the carrier structure 20 by laser, grinding, or etching to expose the circuit layer 202.

As shown in FIG. 2C, a second optoelectronic device 24 is disposed in the groove 200 of the carrier structure 20, and the second optoelectronic device 24 includes a package structure 240, a semiconductor element 241 disposed in the package structure 240, and an optical element 242 mounted onto the package structure 240, so as to form the electronic package 2 of the present disclosure.

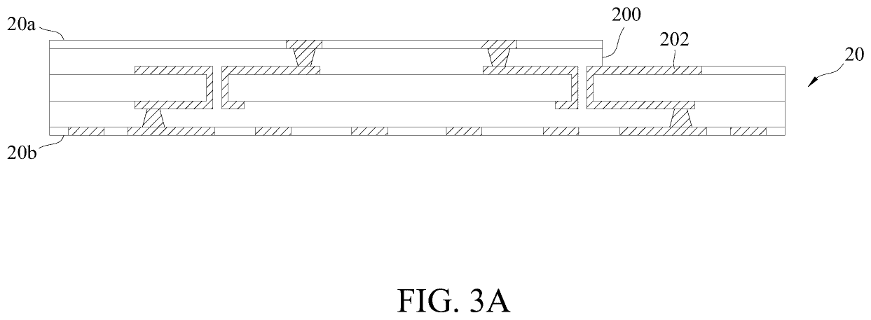

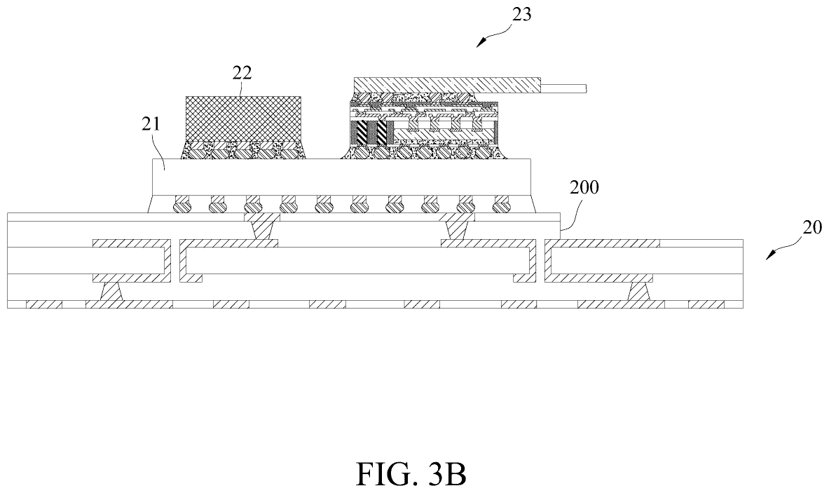

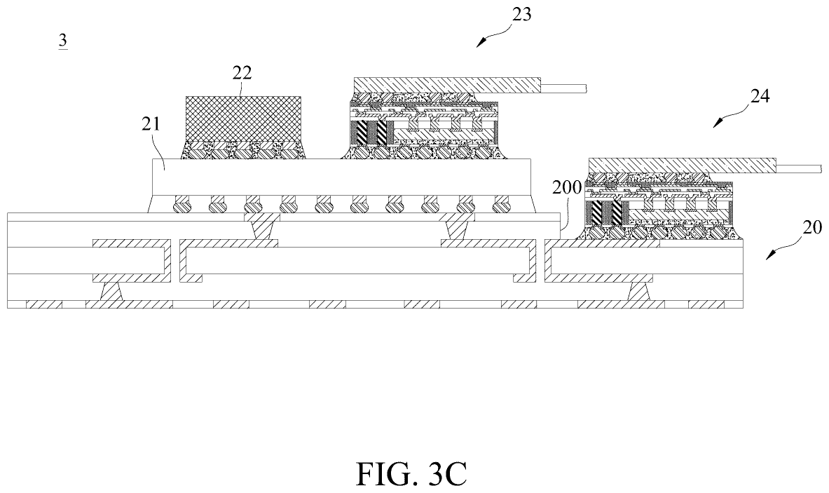

Please refer to FIG. 3A to FIG. 3C, which are schematic cross-sectional views illustrating a manufacturing method of an electronic package 3 according to a second embodiment of the present disclosure. This embodiment is substantially the same as the previous embodiment, and the main difference lies in the disposing timing of the groove of the carrier structure.

As shown in FIG. 3A, a carrier structure 20 is first provided and has at least one circuit layer 202 as well as a first surface 20a and a second surface 20b opposite to the first surface 20a, and a groove 200 is formed on the first surface 20a to expose the circuit layer 202.

As shown in FIG. 3B, a carrier board 21, an electronic element 22 and a first optoelectronic device 23 are disposed on the carrier structure 20, wherein the electronic element 22 and the first optoelectronic device 23 are mounted onto the carrier board 21 and are electrically connected to the carrier board 21, and the carrier board 21 is disposed on the carrier structure 20 and is electrically connected to the carrier structure 20.

As shown in FIG. 3C, a second optoelectronic device 24 is disposed in the groove 200 of the carrier structure 20.

In addition, in the above-mentioned manufacturing process, the second optoelectronic device 24 is also first disposed, and then the first optoelectronic device 23 is disposed to produce the electronic package 3 of the present disclosure.

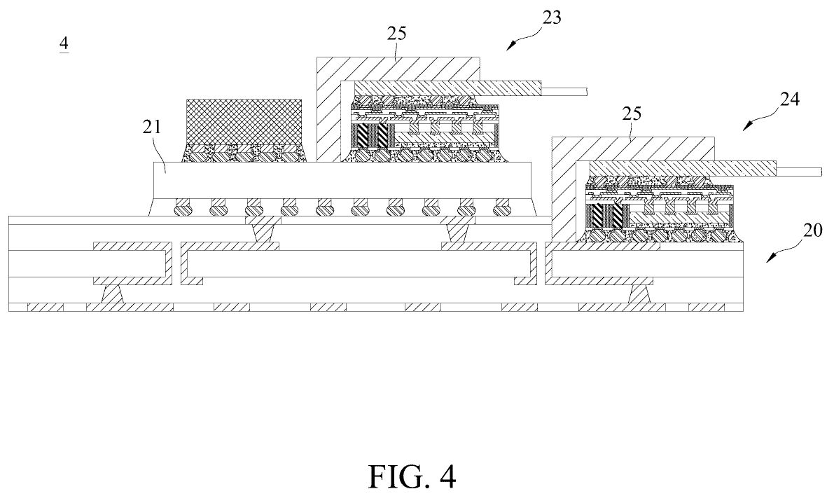

Please refer to FIG. 4, which is a schematic cross-sectional view illustrating a manufacturing method of an electronic package 4 according to a third embodiment of the present disclosure. This embodiment is substantially the same as the previous embodiments, and the main difference is that a heat sink 25 can be optionally connected above the first optoelectronic device 23 and/or the second optoelectronic device 24, and the heat sink 25 is disposed on the carrier board 21 or the carrier structure 20.

Through the aforementioned manufacturing process, the present disclosure further provides an electronic package 2, 3, 4, which comprises: a carrier structure 20 having a circuit layer 202, a first surface 20a and a second surface 20b opposite to the first surface 20a, wherein a groove 200 is formed on the first surface 20a; a carrier board 21 disposed on the first surface 20a of the carrier structure 20; a first optoelectronic device 23 disposed on the carrier board 21; and a second optoelectronic device 24 disposed in the groove 200 of the carrier structure 20. An optical fiber array unit of the first optoelectronic device 23 and an optical fiber array unit of the second optoelectronic device 24 are each connected to at least one optical fiber 26 so that optical signals are transmitted to the first optoelectronic device 23 and the second optoelectronic device 24.

In addition, the electronic package 2, 3, 4 further comprises an electronic element 22 disposed on the carrier board 21.

The electronic package 4 further comprises a heat sink 25, which can be optionally disposed on the first optoelectronic device 23 and/or the second optoelectronic device 24.

To sum up, in the electronic package and the manufacturing method thereof of the present disclosure, a carrier board is additionally disposed on the carrier structure for mounting the first optoelectronic device. At the same time, a groove is formed in the carrier structure for receiving the second optoelectronic device, so that the amount of data transmission is increased by increasing the number of optoelectronic devices. At the same time, the electronic package can be fabricated using the existing semiconductor packaging processes, so that there is no need to develop a special process or purchase special equipment, thereby reducing product production costs.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a carrier structure having a first surface and a second surface opposite to the first surface, wherein the first surface is formed with a groove thereon;
a carrier board disposed on the first surface of the carrier structure and electrically connected to the carrier structure;
a first optoelectronic device disposed on and electrically connected to the carrier board; and
a second optoelectronic device disposed in the groove and electrically connected to the carrier structure.

2. The electronic package of claim 1, further comprising an electronic element disposed on and electrically connected to the carrier board.

3. The electronic package of claim 1, further comprising a heat sink disposed on the first optoelectronic device and/or the second optoelectronic device.

4. The electronic package of claim 1, wherein the first optoelectronic device and the second optoelectronic device are each connected to at least one optical fiber.

5. The electronic package of claim 1, wherein the carrier board is a core substrate with a circuit layer, a coreless substrate with a circuit layer, or an interposer with conductive vias.

6. The electronic package of claim 1, wherein the first optoelectronic device and the second optoelectronic device each comprises a package structure, a semiconductor element disposed in the package structure and an optical element mounted onto the package structure.

7. The electronic package of claim 6, wherein the optical element is an optical module, and the optical module includes a coupler, an optical chip, a total reflection mirror and an optical fiber array unit.

8. The electronic package of claim 6, wherein the optical element is an optical chip.

9. The electronic package of claim 6, wherein the package structure is a fan-out package-on-package structure, and the semiconductor element is an electronic integrated circuit.

10. A method of manufacturing an electronic package, comprising:
disposing a carrier board on a carrier structure, wherein the carrier structure has a first surface and a second surface opposite to the first surface, and a groove is formed on the first surface, wherein the carrier board is disposed on the first surface of the carrier structure and is electrically connected to the carrier structure;
disposing a first optoelectronic device on the carrier board and electrically connecting the first optoelectronic device to the carrier board; and
disposing a second optoelectronic device in the groove and electrically connecting the second optoelectronic device to the carrier structure.

11. The method of claim 10, further comprising disposing an electronic element on the carrier board and electrically connecting the electronic element to the carrier board.

12. The method of claim 10, further comprising disposing a heat sink on the first optoelectronic device and/or the second optoelectronic device.

13. The method of claim 10, wherein the first optoelectronic device and the second optoelectronic device are each connected to at least one optical fiber.

14. The method of claim 10, wherein the carrier board is a core substrate with a circuit layer, a coreless substrate with a circuit layer, or an interposer with conductive vias.

15. The method of claim 10, wherein the first optoelectronic device and the second optoelectronic device each comprises a package structure, a semiconductor element disposed in the package structure and an optical element mounted onto the package structure.

16. The method of claim 15, wherein the optical element is an optical module, and the optical module includes a coupler, an optical chip, a total reflection mirror and an optical fiber array unit.

17. The method of claim 15, wherein the optical element is an optical chip.

18. The method of claim 15, wherein the package structure is a fan-out package-on-package structure, and the semiconductor element is an electronic integrated circuit.
